(19) United States
(12) Patent Application Publication
(10) Pub. No.: US 2006/0180083 A1
(43) Pub. Date: Aug. 17, 2006

(54) Positioning board for positioning heater lines during plasma enhanced CVD (PECVD)

(75) Inventors: Wei-Fang Yang, Chung-Ho City (TW); Pen-Neng Liao, HsinChu (TW); Hsu-Ming Hsieh, HsinChu (TW)

Correspondence Address: TROXELL LAW OFFICE PLLC;SUITE 1404, 5205 LEESBURG PIKE, FALLS CHURCH, VA, 22041, US

(73) Assignee: Zenith Materials Technology Corp.

(21) Appl. No.: 11/055,682

(22) Filed: Feb. 11, 2005

(51) Int. Cl. H01L 21/306; C23F 1/00; C23C 16/00

(52) U.S. Cl. 118/724; 156/345.37; 156/345.52

(57) ABSTRACT

A positioning board used in processes of Plasma Enhanced CVD (PECVD) for positioning a heater line on a heater block includes a pressing portion at an underside thereof and a notch is defined in the pressing portion. The heater line is engaged with the notch when the positioning board is pressed on the heater block so as to secure the heater line.

### FIELD OF THE INVENTION

The present invention relates to a positioning board for positioning heater line of a heater block during process of Plasma Enhanced CVD (PECVD).

### BACKGROUND OF THE INVENTION

Processes for developing films on base boards by using plasma treatment are used in industry of semi-conductor. The development of the film on the base boards includes two main methods which are ion implantation and deposition film. The method of ion implantation employs ion stream of high energy to plant desired type of ions such as ions of arsenic, phosphorus or boron, into the semi-conductor. The method of deposition film employs Chemical Vapor Deposition (CVD) or Physical Vapor Deposition (PVD) to coat reaction vapor on the surface of wafers by way of vapor deposition or sputter deposition. The systems for the CVD includes Atmospheric Pressure CVD (APCVD), Low Pressure CVD (LPCVD) and Plasma Enhanced CVD (PECVD), where the PECVD becomes the most important method for developing film on larger areas of base boards.

In the PECVD process, the wafers are heated by a heater block “A” as shown in FIG. 1 and the heater block “A” is made of metal and a groove “A1” is defined in an outer surface of the heater block “A” so as to receive a heater line “B” therein. The heater line “B” includes a heater coated with magnesium powder so as not to interfere with high frequency of RF signal on the heater block “A”. A metal tube is then mounted onto the heater to make the heater line. A positioning board “C” is soldered on the heater block “A” to cover up the groove “A1” in which the heater line “B” is received.

However, the conventional positioning board “C” has a flat underside and the heater line “B” is in tubular shape so that the positioning board “C” contacts the heater line “B” only at one point as shown in FIG. 2a or even a gap is defined between the positioning board “C” and the heater line “B” as shown in FIG. 2b. Some shortcomings are therefore found:

1. It is difficult to press the positioning board “C” on the heater line “B”. While in use, under the high working temperature of 400° C., heat is trapped at a small area of the heater line “B” and the material of that area could melt. And the coated magnesium powder thus releases from that area to further interfere with the high frequency RF signals. This leads the circuit to be cut off.

2. When the system needs to be maintained, the high working temperature has to be reduced so that the heater line “B” shrink under lower temperature and are dragged to become loosened. The high temperature of the heater line “B” cannot be transferred to the heater block “A”. This may cause melting of the heater line “B” to short the circuit, or cause the heater line “B” being dragged and broken to shut down the whole heater block “A”.

3. The size of the groove “A1” is changed after all the accumulations attached in the groove “A1” are cleaned up and when the positioning board “C” is re-installed to the heater line “B”, there is a gap formed therebetween. The heater line “B” could melt because no enough contact area for transferring the heat between the positioning board “C” and the heater line “B”.

The present invention intends to provide a positioning board which has a notch for securely engaging with the heater line so that the contact area between the positioning board and the heater line is increased.

### SUMMARY OF THE INVENTION

The present invention relates to a positioning board used in processes of Plasma Enhanced CVD (PECVD) for positioning a heater line on a heater block. The positioning board has a pressing portion at an underside thereof defined as a notch. The notch engages the heater line to increase the contact area between the positioning board and the heater.

The present invention will become more obvious from the following description when taken in connection with the accompanying drawings that show, for purposes of illustration only, a preferred embodiment in accordance with the present invention.

### BRIEF DESCRIPTION OF THE DRAWINGS

FIG. 1 is an exploded view to show the conventional positioning board, heater block and heater line;

FIG. 2a shows a cross sectional view of one embodiment of the connection of the conventional positioning board and the heater block;

FIG. 2b shows a cross sectional view of the other embodiment of the connection of the conventional positioning board and the heater block;

FIG. 3 is an exploded view to show the positioning board, heater block and heater line of the present invention;

FIG. 4a shows a cross sectional view of the positioning board and the heater block of the present invention before connection;

FIG. 4b is a cross sectional view to show the connection of the positioning board and the heater block of the present invention, and

FIG. 5 is a perspective view of the positioning board on the heater block of the present invention.

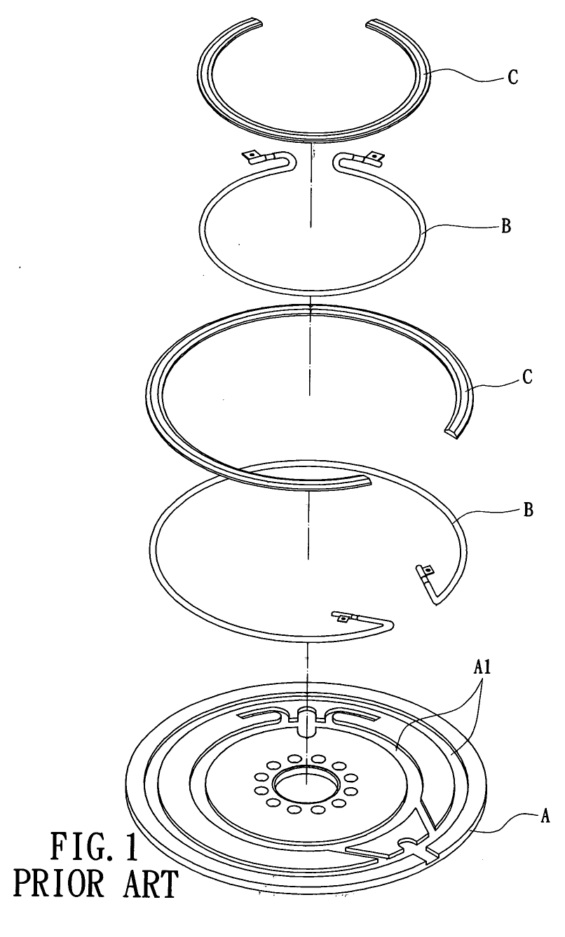

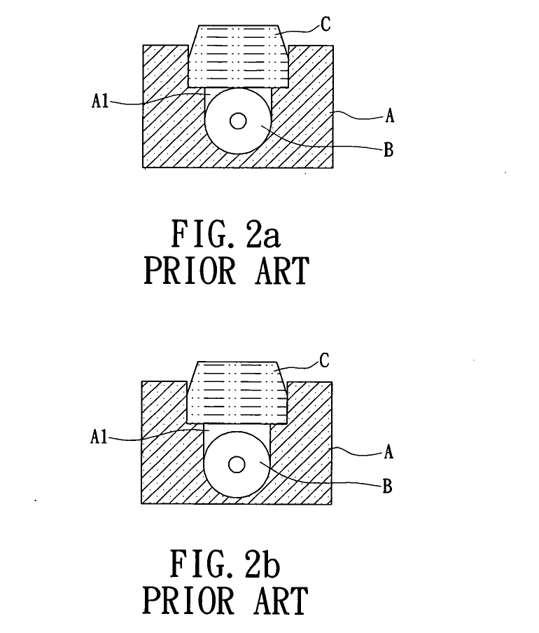

### DETAILED DESCRIPTION OF THE PREFERRED EMBODIMENT

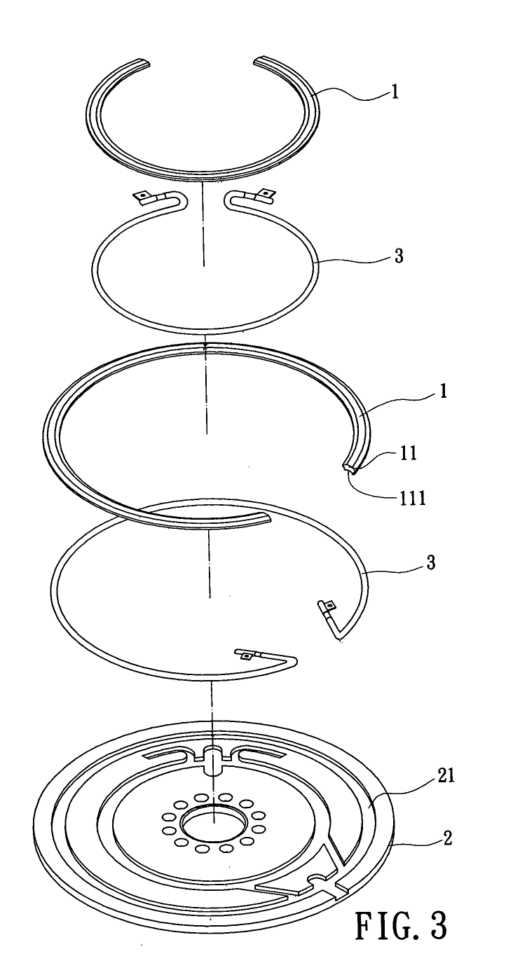

Referring to FIGS. 3-5, an embodiment of the positioning board 1 of the present invention is disclosed.

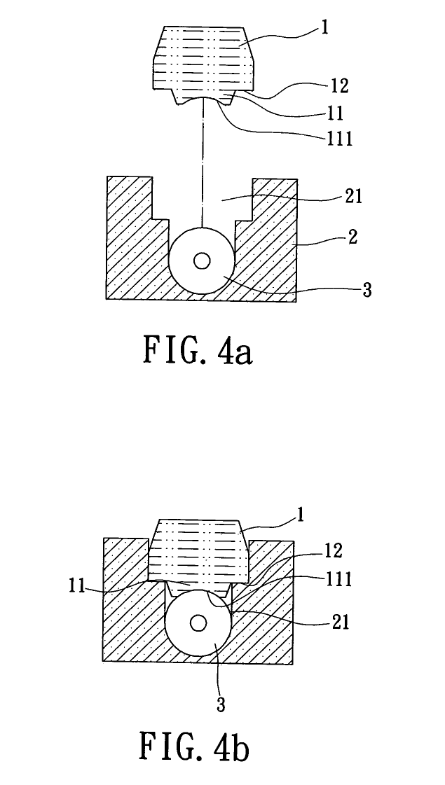

The positioning board 1 is used in processes of Plasma Enhanced CVD (PECVD) for positioning a heater line 3 on a heater block 2. The positioning board 1 has a pressing portion 11 extending from an underside thereof and an arcuate notch 111 is defined in the pressing portion 11. The shape of the arcuate notch 111 is supplementary to the shape of the heater line 3 as shown in FIGS. 4a and 4b so that the heater line 3 is fitted in the arcuate notch 111.

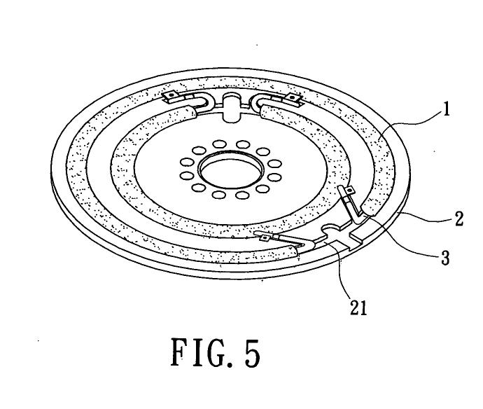

As shown in FIGS. 4b and 5, when the positioning board 1 is mounted on the heater block 2, the heater line 3 is fitted well in the arcuate notch 111. And further two wings 12 extend from two sides of the positioning board 1 so as to press the positioning board 1 on the heater block 2.

In use, further referring to FIG. 3-5, first to position a heat line 3 in the groove 21 of the heat block 2 and to press therealong by the pressing portion 11 thereof the underside of the positioning board 1. When pressing on the heat line 3, the two wings 12 of the positioning board 1 are fixed effectively on the groove 21, and the arcuate notch 111 of the pressing portion 11 ensures that the heater line 3 is well positioned and the contact area therebetween the heater line 3 and the positioning board 1 is increased so that heat of the heater line 3 can be transferred therefrom. The positioning board 1 is then soldered to the heater block 2.

Thus, the present invention has the following advantages:

1. With the pressing portion thereunder the positioning board, when in installment, the positioning board is fitted well on the heat line without having a gap therebetween. Further, the pressing portion is defined as an arcuate notch, it can further engage the heat line well to increase the contact area therebetween. Thus when in use, the heat of the heat line can be easily transferred therefrom and the problem of melting of the heater line is then improved. This can also expand the usage life of the positioning board.

2. In maintenance, even if the size of the groove is changed, the heater line and the positioning board are still well engaged with each other by the engagement of the arcuate notch and the heater line. This can avoid the problem of melting of a heat line.

While we have shown and described the embodiment in accordance with the present invention, it should be clear to those skilled in the art that further embodiments may be made without departing from the scope of the present invention.

What is claimed is:

1. A positioning board used in processes of Plasma Enhanced CVD (PECVD) for positioning a heater line on a heater block, wherein the positioning board has a pressing portion at an underside thereof defined as a notch, the notch being adapted to engage the heater line.

2. The positioning board as claimed in claim 1, wherein two wings extend from two sides of the positioning board so as to be adapted to press the positioning board on the heater block.

3. The positioning board as claimed in claim 1, wherein the shape of the notch is supplementary to the shape of the heater line.
